(19) United States
(12) Patent Application Publication
(10) Pub. No.: US 2023/0267238 A1
(43) Pub. Date: Aug. 24, 2023

(54) NAVIGATION SIMULATOR, INFORMATION PROCESSING DEVICE, AND RECORDING MEDIUM

(71) Applicant: Panasonic Intellectual Property Management Co., Ltd., Osaka (JP)

(72) Inventors: Yu HASEGAWA, Kanagawa (JP); Ichiro FURUYA, Kanagawa (JP)

(21) Appl. No.: 18/163,739

(22) Filed: Feb. 2, 2023

(30) Foreign Application Priority Data
Feb. 21, 2022 (JP) 2022-025088

(51) Int. Cl. G06F 30/10; G01C 25/00

(52) U.S. Cl. CPC G06F 30/10; G01C 25/00; G01C 21/28

(57) ABSTRACT

A navigation simulator includes a memory in which a computer program is stored and a processor coupled to the memory. The processor performs processing by executing the computer program. The processing includes acquiring, from an external device, a test scenario including a simulator built-in sensor signal. The simulator built-in sensor signal represents motion information detected by a simulator built-in sensor when a vehicle drives on a preset driving route. The simulator built-in sensor is installed in the navigation simulator. The processing includes generating an emulated sensor signal obtained by emulating a car navigator built-in sensor signal on the basis of the simulator built-in sensor signal included in the test scenario. The car navigator built-in sensor signal represents motion information detected by a car navigator built-in sensor installed in a car navigation system. The processing includes outputting the generated emulated sensor signal to the car navigation system.

### CROSS-REFERENCE TO RELATED APPLICATIONS

This application is based upon and claims the benefit of priority from Japanese Patent Application No. 2022-025088, filed on Feb. 21, 2022, the entire contents of which are incorporated herein by reference.

### FIELD

Embodiments described herein relate generally to a navigation simulator, an information processing device, and a recording medium.

### BACKGROUND

There have been developed technologies of performing operation verification of car navigation by a desktop simulation system. For example, technologies that have been developed include a technology in which a car navigation system being a test target is placed on a turntable-type rotary platform, and the turntable is rotated in accordance with a global navigation satellite system (GNSS) signal output from a GNSS simulator to simulate a driving state such as turning of a vehicle (for example, JP H5-108009 A and JP 2014-98994 A).

However, in the above-described technology, the driving state of the vehicle is simulated only by turning of the rotary table, so that the driving state of the vehicle can be reproduced only by one-axis rotation. Therefore, there are problems that it is difficult to simulate a sensor such as an acceleration sensor installed in the vehicle and the size of the system may get larger.

### SUMMARY

A navigation simulator according to the present disclosure includes a memory in which a computer program is stored and a processor coupled to the memory. The processor is configured to perform processing by executing the computer program. The processing includes acquiring, from an external device, a test scenario including a simulator built-in sensor signal. The simulator built-in sensor signal represents motion information detected by a simulator built-in sensor when a vehicle drives on a preset driving route. The simulator built-in sensor is installed in the navigation simulator. The processing includes generating an emulated sensor signal obtained by emulating a car navigator built-in sensor signal on the basis of the simulator built-in sensor signal included in the test scenario. The car navigator built-in sensor signal represents motion information detected by a car navigator built-in sensor installed in the car navigation system. The processing includes outputting the generated emulated sensor signal to a car navigation system.

### BRIEF DESCRIPTION OF THE DRAWINGS

FIG. 1 is a diagram illustrating an example of a configuration of an information processing system according to the present embodiment;

FIG. 2 is a diagram illustrating an example of a functional configuration of a navigation simulator HW according to the present embodiment;

FIG. 3 is a diagram illustrating an example of a functional configuration of a PC according to the present embodiment;

FIG. 4 is a flowchart illustrating an example of a flow of a recording process of actual vehicle driving test log data in the information processing system according to the present embodiment;

FIG. 5 is a flowchart illustrating an example of a flow of a generation process of virtual driving route data in the information processing system according to the present embodiment;

FIG. 6 is a flowchart illustrating an example of a flow of an output process of a navigation simulator scenario in the information processing system according to the present embodiment;

FIG. 7 is a diagram illustrating an example of an execution process of a navigation simulator scenario in the information processing system according to the present embodiment;

FIG. 8 is a diagram illustrating an example of an execution process of a navigation simulator scenario in the information processing system according to the present embodiment; and

FIG. 9 is a diagram illustrating an example of an execution process of a navigation simulator scenario in the information processing system according to the present embodiment.

### DETAILED DESCRIPTION

Hereinafter, embodiments of a navigation simulator, an information processing device, and a recording medium according to the present disclosure will be described with reference to the drawings.

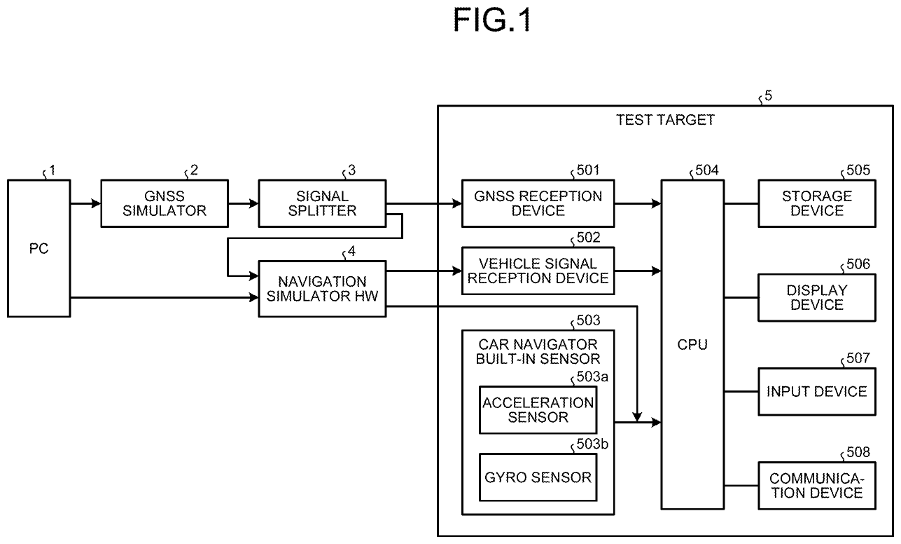

FIG. 1 is a diagram illustrating an example of a configuration of the information processing system according to the present embodiment. As illustrated in FIG. 1, the information processing system according to the present embodiment includes a personal computer (PC) 1, a global navigation satellite system (GNSS) simulator 2, a signal splitter 3, a navigation simulator HW 4, and a test target 5.

The PC 1 is an example of an information processing device. The PC 1 generates a GNSS simulation scenario and a navigation simulator scenario on the basis of actual vehicle driving test log data (an example of a driving log file) or virtual driving route data (an example of a virtual driving scenario).

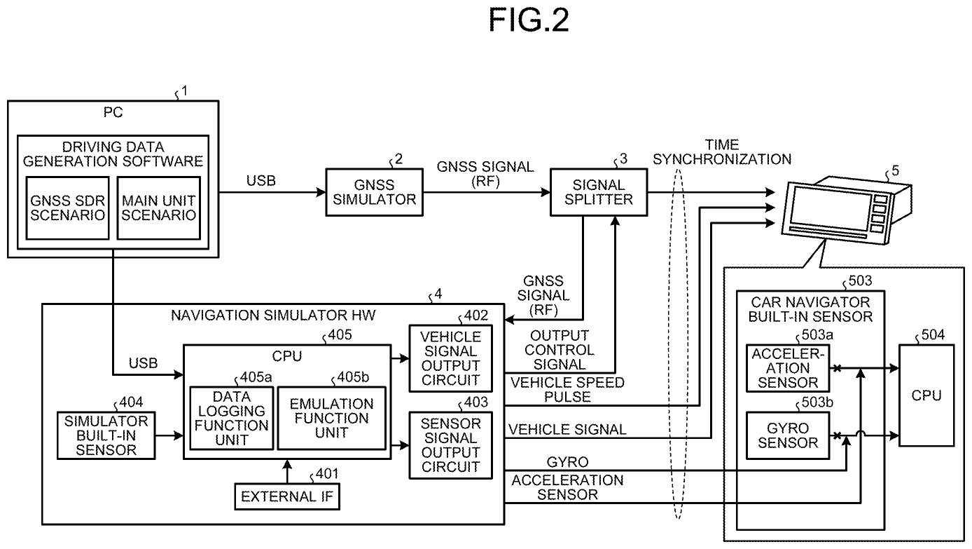

The actual vehicle driving test log data includes a simulator built-in sensor signal. The simulator built-in sensor signal represents motion information (for example, angular velocity and acceleration) detected by a simulator built-in sensor 404 (refer to FIG. 2). The simulator built-in sensor signal is represented by a dimensionless quantity. The simulator built-in sensor 404 is installed in the navigation simulator HW 4. In the present embodiment, the actual vehicle driving test log data includes a vehicle signal representing vehicle information (for example, vehicle speed and CAN information). The vehicle information is acquired by the navigation simulator HW 4.

The virtual driving route data includes a virtual sensor signal. The virtual sensor signal represents motion information detected by the simulator built-in sensor in a case where the vehicle virtually drives on a preset driving route. The virtual sensor signal is represented by a physical quantity. In the present embodiment, the virtual driving route data includes a vehicle signal regarding a vehicle in a case where the vehicle virtually drives on a preset driving route.

The GNSS simulation scenario includes position information and time information regarding a vehicle that drives on a preset driving route. Moreover, the navigation simulator scenario is an example of a test scenario that includes a simulator built-in sensor signal or a virtual sensor signal. In the present embodiment, the navigation simulator scenario includes position information and time information of a vehicle driving on a preset driving route, in addition to the simulator built-in sensor signal or the virtual sensor signal.

The GNSS simulator 2 is connected to the PC 1. The GNSS simulator 2 generates, by means of simulation, a GNSS signal representing position information of the vehicle (hereinafter, referred to as an emulated GNSS signal) on the basis of position information included in the GNSS simulator scenario generated by the PC 1. In one example, the GNSS simulator 2 is connected to the PC 1 by a serial bus standard such as a universal serial bus (USB) or Ethernet (registered trademark). The GNSS simulator 2 outputs the emulated GNSS signal and the time information to the signal splitter 3. The GNSS simulator 2 is also referred to as a signal generator.

The signal splitter 3 outputs, to the test target 5, the emulated GNSS signal and time information that are output from the GNSS simulator 2 by radio frequency (RF) or the like. Moreover, the signal splitter 3 outputs, to the navigation simulator HW 4, the emulated GNSS signal and the time information that are output from the GNSS simulator 2.

The navigation simulator HW 4 (an example of a navigation simulator) is connected to the PC 1 via a serial bus standard such as USB. The navigation simulator HW 4 acquires the navigation simulator scenario from the PC 1. The navigation simulator HW 4 generates an emulated sensor signal obtained by emulating a car navigator built-in sensor signal on the basis of a simulator built-in sensor signal or a virtual sensor signal included in the navigation simulator scenario. The car navigator built-in sensor signal represents motion information detected by a car navigator built-in sensor 503 installed in the test target 5. The navigation simulator HW 4 outputs the generated emulated sensor signal to the test target 5. In addition, based on the vehicle signal included in the navigation simulator scenario, the navigation simulator HW 4 generates an emulated vehicle signal obtained by emulating the vehicle signal regarding the vehicle and outputs the generated emulated vehicle signal to the test target 5.

In the present embodiment, based on the emulated GNSS signal and the time information input from the signal splitter 3, the navigation simulator HW 4 outputs the emulated sensor signal and the emulated vehicle signal to the test target 5 in synchronization with the output of the emulated GNSS signal from the signal splitter 3 to the test target 5.

The test target 5 is an example of an in-vehicle device or a car navigation system installed in a vehicle. In the present embodiment, the test target 5 is provided with a GNSS reception device 501, a vehicle signal reception device 502, a car navigator built-in sensor 503, a central processing unit (CPU) 504, a storage device 505, a display device 506, an input device 507, and a communication device 508.

The GNSS reception device 501 is, for example, a global positioning system (GPS) receiver. The GNSS reception device 501 measures the position of the vehicle by using a signal emitted from an artificial satellite and receives a GNSS signal (for example, a GPS signal) indicating the measured position. The GNSS reception device 501 converts the received GNSS signal into positioning information including time information. The GNSS reception device 501 outputs the converted positioning information to the CPU 504. In addition, when verifying the operation of the test target 5, the GNSS reception device 501 receives the emulated GNSS signal from the signal splitter 3 and outputs the emulated GNSS signal to the CPU 504.

The vehicle signal reception device 502 receives vehicle signals such as a vehicle speed pulse and CAN information from the vehicle via a vehicle harness, and outputs the received vehicle signals to the CPU 504. In addition, when verifying the operation of the test target 5, the vehicle signal reception device 502 receives the emulated vehicle signal from the navigation simulator HW 4 and outputs the received emulated vehicle signal to the CPU 504.

The car navigator built-in sensor 503 detects vehicle motions such as rotation, inclination, and acceleration of the vehicle. The car navigator built-in sensor 503 outputs, to the CPU 504, a car navigator built-in sensor signal representing information corresponding to the detected motion. As the car navigator built-in sensor signal, the car navigator built-in sensor 503 outputs angular velocity when rotation of the vehicle is detected, and outputs an acceleration when acceleration of the vehicle is detected, for example. In the present embodiment, the car navigator built-in sensor 503 includes an acceleration sensor 503a and a gyro sensor 503b. The acceleration sensor 503a detects acceleration and inclination of the vehicle. The gyro sensor 503b detects rotation of the vehicle.

The storage device 505 stores various types of information (for example, position information, time information, a vehicle signal, and a sensor signal) used for car navigation. The display device 506 displays route guidance information related to route guidance by car navigation. The input device 507 inputs various types of information such as a destination for the car navigation. The communication device 508 serves to perform communication between an external device and the test target 5.

The CPU 504 performs computation related to car navigation (for example, a route search) on the basis of a GNSS signal output from the GNSS reception device 501, a vehicle signal output from the vehicle signal reception device 502, a car navigator built-in sensor signal output from the car navigator built-in sensor 503, and the like. In addition, when verifying the operation of the test target 5, the CPU 504 performs computation related to car navigation on the basis of signals such as the emulated GNSS signal received by the GNSS reception device 501, the emulated vehicle signal received by the vehicle signal reception device 502, and the emulated sensor signal input from the navigation simulator HW 4 via a dedicated signal line.

FIG. 2 is a diagram illustrating an example of a functional configuration of the navigation simulator HW 4 according to the present embodiment. Next, an example of a functional configuration of the navigation simulator HW 4 according to the present embodiment will be described with reference to FIG. 2.

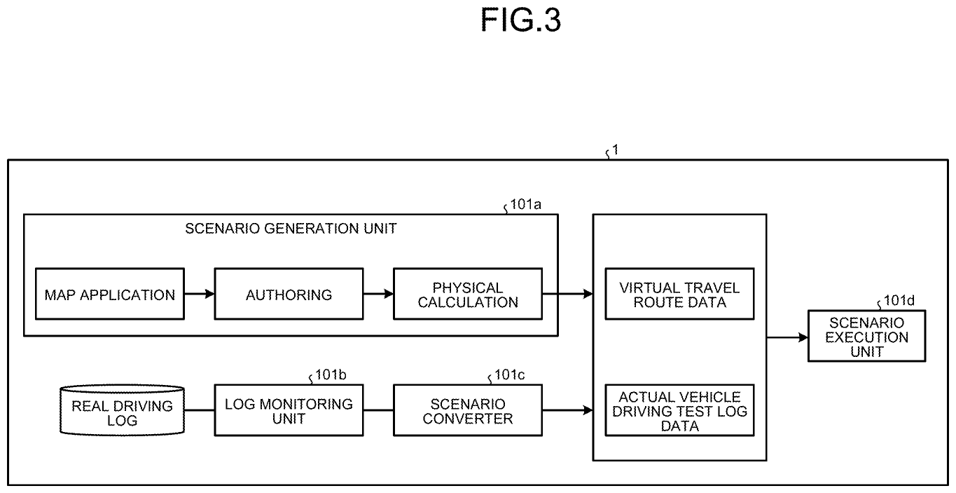

As illustrated in FIG. 2, the navigation simulator HW 4 according to the present embodiment includes an external IF 401, a vehicle signal output circuit 402, a sensor signal output circuit 403, a simulator built-in sensor 404, and a CPU 405. The navigation simulator HW 4 according to the present embodiment includes devices (not illustrated) such as read only memory (ROM), random access memory (RAM), and a communication device. The communication device serves to perform communication with an external device such as the PC 1. The ROM is an example of memory that stores various computer programs. The RAM is a work area used when the CPU 405 executes a computer program. The CPU 405 is an example of a processor and a computer, which execute a computer program stored in the ROM by using the RAM as a work area to implement a data logging function unit 405a and an emulation function unit 405b as illustrated in FIG. 3. This may be paraphrased as that, the navigation simulator HW 4 includes the data logging function unit 405a and the emulation function unit 405b. The data logging function unit 405a and the emulation function unit 405b may be implemented by different pieces of hardware.

The external IF 401 includes, for example, a GNSS antenna connector, a vehicle IF, a power connector, a GNSS receiver IF, an SD card slot, and the like. The GNSS antenna connector is connected to the GNSS antenna. The vehicle IF acquires vehicle information such as a vehicle speed pulse, CAN information, reverse, illumination, and parking. In one example, the power connector supplies power to the navigation simulator HW 4 from the vehicle's cigarette lighter power source or power source AC adapter. The GNSS receiver IF is connected to a GNSS receiver built in the navigation simulator HW 4. The SD card slot is a slot that can be connected to a storage unit such as an SD card that stores various types of information including the actual vehicle driving test log data.

The vehicle signal output circuit 402 outputs the emulated vehicle signal to the test target 5. The sensor signal output circuit 403 outputs the emulated sensor signal to the test target 5. The simulator built-in sensor 404 includes an acceleration sensor, a gyro sensor, and the like, detects vehicle's motion information such as angular velocity and acceleration, and outputs a simulator built-in sensor signal representing the detected motion information to the CPU 405.

The data logging function unit 405a acquires the GNSS signal through the external IF 401 and stores the acquired GNSS signal in the SD card with an NMEA format. The external IF 401 that acquires the GNSS signal is the GNSS receiver IF, for example. In addition, the data logging function unit 405a acquires information such as a vehicle speed pulse and CAN information, for example, which is acquired by the external IF 401. The external IF 401 that acquires the vehicle speed pulse and the CAN information is the vehicle IF, for example. The data logging function unit 405a calculates the vehicle speed on the basis of the vehicle speed pulse, and stores the vehicle signal indicating the vehicle speed and the CAN information, etc. in the SD card. In addition, the data logging function unit 405a acquires a simulator built-in sensor signal output from the simulator built-in sensor 404 and stores the acquired signal in the SD card. In the present embodiment, the SD card functions as an example of a storage medium that stores actual vehicle driving test log data including a simulator built-in sensor signal.

The emulation function unit 405b acquires the navigation simulator scenario from the PC 1 (an example of an external device and an information processing device). The emulation function unit 405b is an example of a scenario acquisition unit. The simulator scenario includes a simulator built-in sensor signal included in the actual vehicle driving test log data, or includes a virtual sensor signal as the simulator built-in sensor signal. In addition, the emulation function unit 405b generates an emulated sensor signal on the basis of a simulator built-in sensor signal or a virtual sensor signal included in the navigation simulator scenario. The emulated sensor signal is a signal obtained by emulating an electrical signal necessary for car navigation in the test target 5. Specifically, based on a simulator built-in sensor signal or a virtual sensor signal included in the navigation simulator scenario, the emulation function unit 405b generates an emulated sensor signal obtained by emulating the car navigator built-in sensor signal output by the car navigator built-in sensor 503. In one example, the emulated sensor signal may be a signal obtained by converting a simulator built-in sensor signal or a virtual sensor signal into a signal with a format of a car navigator built-in sensor signal output by the car navigator built-in sensor 503. In addition, based on the vehicle signal included in the navigation simulator scenario, the emulation function unit 405b generates an emulated vehicle signal obtained by emulating a vehicle signal regarding the vehicle.

With the configuration above, the sensor signal necessary for the operation verification of the test target 5 can electrically be reproduced. Therefore, it is possible to execute operation verifications on the test target 5 (for example, reproduction of a real driving log, pre-verification before real local driving, and driving route verification that is impossible in reality, such as wrong-way-driving). The real driving refers to driving of a real vehicle. In addition, it is possible to verify the operation of the test target 5 without using large mechanical equipment such as a turntable. In the present embodiment, the emulation function unit 405b operates as a scenario acquisition unit and an emulation function unit. In other words, the CPU 405 implements a scenario acquisition unit by executing a program stored in the ROM using the RAM as a work area. This may be paraphrased as that the navigation simulator HW 4 includes the scenario acquisition unit. The scenario acquisition unit and the emulation function unit may be implemented by different pieces of hardware.

FIG. 3 is a diagram illustrating an example of a functional configuration of the PC according to the present embodiment. Next, an example of a functional configuration of the PC 1 according to the present embodiment will be described with reference to FIG. 3.

The PC 1 according to the present embodiment includes a CPU, ROM, RAM, a communication device, and the like. The communication device serves to perform communication with an external device such as the navigation simulator HW 4. The ROM stores various programs such as driving data generation software. The RAM is a work area when the CPU executes various programs such as driving data generation software. The CPU executes driving data generation software stored in the ROM using the RAM as a work area, thereby implementing a scenario generation unit 101a, a log monitoring unit 101b, a scenario converter 101c, and a scenario execution unit 101d as illustrated in FIG. 3. This may be paraphrased as that the PC 1 includes the scenario generation unit 101a, the log monitoring unit 101b, the scenario converter 101c, and the scenario execution unit 101d. The scenario generation unit 101a, the log monitoring unit 101b, the scenario converter 101c, and the scenario execution unit 101d may be implemented by a plurality of different pieces of hardware, or may be each implemented by a different piece of hardware.

The scenario generation unit 101a is an example of a generation unit that generates virtual driving route data. In the present embodiment, by means of a dedicated map application, the scenario generation unit 101a generates a driving route on which the vehicle virtually drives. In addition, based on the generated driving route, the scenario generation unit 101a generates virtual driving route data including vehicle position information, a vehicle signal, and a sensor signal, each relating to a case where the vehicle virtually drives on the driving route. The virtual driving route data includes a GNSS signal representing position information of the vehicle, for example. Hereinafter, the description may be made without distinction between the GNSS signal representing the position information and the position information itself.

The scenario generation unit 101a acquires, by using the map application, the latitude and longitude of the driving route on which verification of operation of the test target 5 is to be performed. Next, based on the acquired latitude and longitude, the scenario generation unit 101a creates, by authoring, a driving route on which verification of the operation of the test target 5 is to be performed. Subsequently, by means of a physical computation, the scenario generation unit 101a generates, as virtual driving route data, vehicle position information, a vehicle signal, a sensor signal, and the like obtained when the vehicle model drives on the created driving route.

The log monitoring unit 101b is an example of a log acquisition unit that acquires actual vehicle driving test log data (in other words, a real driving log) from a storage unit such as an SD card connected to the navigation simulator HW 4. The scenario converter 101c converts a simulator built-in sensor signal included in the actual vehicle driving test log data acquired by the log monitoring unit 101b into actual vehicle driving test log data represented by a physical quantity.

The scenario execution unit 101d is an example of an execution unit that executes a navigation simulator scenario including a virtual sensor signal included in the virtual driving route data or a simulator built-in sensor signal included in the actual vehicle driving test log data. In addition, the scenario execution unit 101d also functions as an example of an output unit that outputs the navigation simulator scenario to the navigation simulator HW 4.

Moreover, the scenario execution unit 101d calculates a transformation rotation matrix corresponding to the attachment angle of the car navigator built-in sensor 503. Specifically, the transformation rotation matrix is a rotation matrix for converting a virtual sensor signal included in the virtual driving route data or a simulator built-in sensor signal included in the actual vehicle driving test log data into a sensor signal corresponding to a coordinate system that is unique to the car navigator built-in sensor 503. Subsequently, the scenario execution unit 101d multiplies, by the calculated transformation rotation matrix, the virtual sensor signal included in the virtual driving route data or the simulator built-in sensor signal included in the actual vehicle driving test log data. With the operation above, the scenario execution unit 101d converts the virtual sensor signal or the simulator built-in sensor signal into a sensor signal corresponding to the coordinate system that is unique to the car navigator built-in sensor 503.

Moreover, the scenario execution unit 101d multiplies the virtual sensor signal or the simulator built-in sensor signal, which has been multiplied by the transformation rotation matrix, by a transformation formula corresponding to the sensitivity coefficient of the car navigator built-in sensor 503 installed in the test target 5. Subsequently, the scenario execution unit 101d executes the navigation simulator scenario including the simulator built-in sensor signal or the virtual sensor signal, which has been multiplied by the transformation formula.

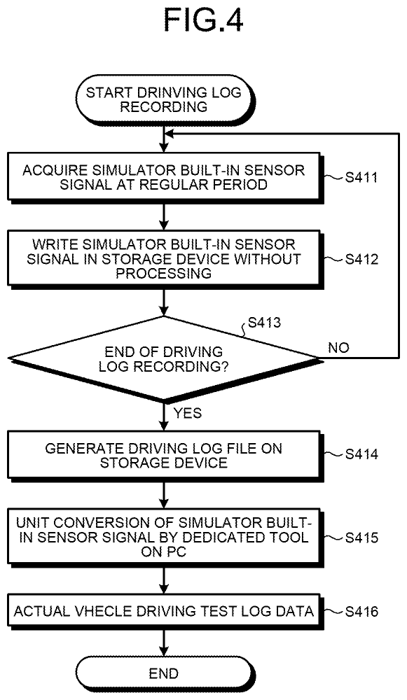

FIG. 4 is a flowchart illustrating an example of a flow of a recording process of actual vehicle driving test log data in the information processing system according to the present embodiment. An example of a flow of recording process of actual vehicle driving test log data in the information processing system according to the present embodiment will be described with reference to FIG. 4.

When the navigation simulator HW 4 is installed in the vehicle and the vehicle starts driving on a preset driving route, the data logging function unit 405a of the navigation simulator HW 4 acquires a simulator built-in sensor signal output from the simulator built-in sensor 404 at a preset period (for example, a regular period) (step S411). The simulator built-in sensor signal is a sensor signal represented by a dimensionless quantity that is unique to the simulator built-in sensor 404. In one example, the simulator built-in sensor signal is represented by using a unit LSB.

Next, the data logging function unit 405a writes the acquired simulator built-in sensor signal in a storage device, such as an SD card, without modification (step S412). Next, the data logging function unit 405a determines whether the recording of the acquired simulator built-in sensor signal (in other words, the driving log) is completed (step S413). The simulator built-in sensor signal is included in the driving log. Hereinafter, in some cases, the simulator built-in sensor signal and the driving log will be described without distinction between them. In a case where the driving of the vehicle on the preset driving route is not completed, the data logging function unit 405a determines that the recording of the driving log is not completed (step S413: No). The data logging function unit 405a then returns to step S411 to continue the acquisition of the simulator built-in sensor signal from the simulator built-in sensor 404.

In contrast, in a case where the driving of the vehicle on the preset driving route is completed, the data logging function unit 405a determines that the recording of the driving log is completed (step S413: Yes). In this case, the data logging function unit 405a generates actual vehicle driving test log data including the simulator built-in sensor signal, which has been written in the SD card (step S414). The actual vehicle driving test log data is an example of a driving log file. In the present embodiment, the actual vehicle driving test log data is binary format data that directly describes a simulator built-in sensor signal output from the simulator built-in sensor 404.

The log monitoring unit 101b of the PC 1 acquires actual vehicle driving test log data from the SD card connected to the navigation simulator HW 4. Then, the log monitoring unit 101b converts a simulator built-in sensor signal included in the actual vehicle driving test log data into a sensor signal represented by a physical quantity (step S415), and thereby completes the actual vehicle driving test log data (step S416). The physical quantity is, for example, a quantity represented using a unit dps or a unit g.

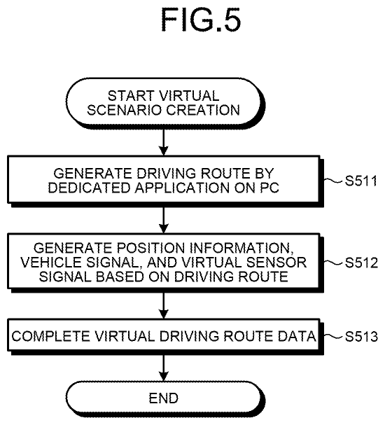

FIG. 5 is a flowchart illustrating an example of a flow of a generation process of virtual driving route data in the information processing system according to the present embodiment. Next, an example of a flow of generation process of virtual driving route data in the information processing system according to the present embodiment will be described with reference to FIG. 5.

First, the scenario generation unit 101a of the PC 1 generates, by using a dedicated application, a driving route on which the vehicle virtually drives (step S511). Next, based on the generated driving route, the scenario generation unit 101a generates vehicle position information, a vehicle signal, a virtual sensor signal, and the like obtained in a case where the vehicle virtually drives on the driving route (step S512). The virtual sensor signal includes, for example, angular velocity expressed by using a unit of dps and acceleration expressed by a unit of g. Subsequently, the scenario generation unit 101a completes virtual driving route data including the generated position information, vehicle signal, virtual sensor signal, and so forth (step S513).

In one example, the scenario generation unit 101a causes the vehicle model to drive on a driving route generated by the dedicated application. At that time, the scenario generation unit 101a causes the vehicle model to drive according to a preset driving condition (for example, maximum speed, wheelbase, shift, or acceleration/deceleration). Subsequently, the scenario generation unit 101a generates vehicle position information, a vehicle signal, a virtual sensor signal, and the like for each preset period (for example, 100 ms).

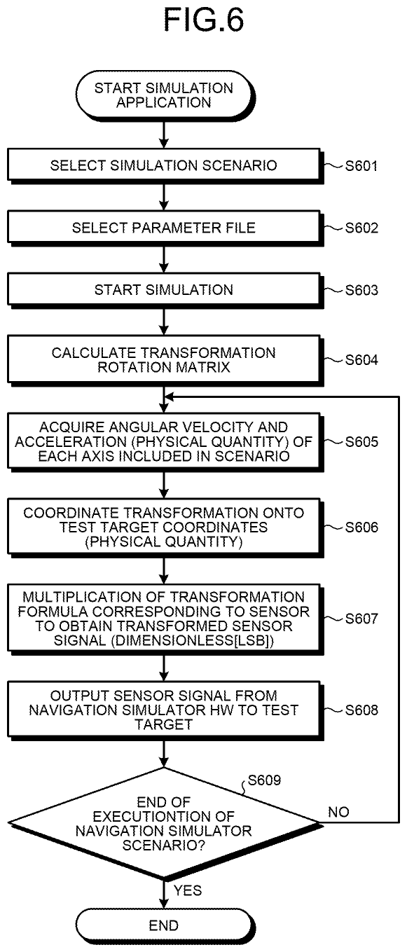

FIG. 6 is a flowchart illustrating an example of a flow of output process of a navigation simulator scenario in the information processing system according to the present embodiment. Next, an example of a flow of an output process of a navigation simulator scenario in the information processing system according to the present embodiment will be described with reference to FIG. 6.

The scenario execution unit 101d of the PC 1 first selects a scenario to be used for executing the navigation simulator scenario from among the actual vehicle driving test log data and the virtual driving route data (step S601). Hereinafter, in some cases, the scenario used for executing the navigation simulator scenario will be referred to as a simulation scenario. Next, the scenario execution unit 101d selects a parameter file corresponding to the test target 5 from among the parameter files stored in the storage unit such as the ROM 102 included in the PC 1 (step S602).

The parameter file includes information representing a sensitivity coefficient and an attachment angle each being unique to the car navigator built-in sensor 503 installed in the test target 5. Next, the scenario execution unit 101d starts a simulation of executing the navigation simulator scenario (step S603).

Next, based on the attachment angle included in the selected parameter file, the scenario execution unit 101d calculates a transformation rotation matrix for converting the virtual sensor signal or the simulator built-in sensor signal included in the selected simulation scenario into the sensor signal corresponding to the coordinate system unique to the test target 5 (step S604). Next, the scenario execution unit 101d acquires a virtual sensor signal or a simulator built-in sensor signal included in the selected simulation scenario and represented by a physical quantity (step S605). For example, the scenario execution unit 101d acquires a virtual sensor signal or a simulator built-in sensor signal corresponding to a plurality of axes (for example, three axes of x, y, and z). The plurality of axes corresponds to a coordinate system used when motion information such as angular velocity and acceleration is detected by the car navigator built-in sensor 503.

Subsequently, the scenario execution unit 101d multiplies the acquired virtual sensor signal or simulator built-in sensor signal by the calculated transformation rotation matrix. In this manner, the scenario execution unit 101d performs coordinate transformation of the virtual sensor signal or the simulator built-in sensor signal included in the selected simulation scenario into a sensor signal corresponding to the coordinate system unique to the car navigator built-in sensor 503 (step S606).

Next, the scenario execution unit 101d multiplies the virtual sensor signal or the simulator built-in sensor signal subjected to coordinate transformation by a transformation formula corresponding to a sensitivity coefficient unique to the car navigator built-in sensor 503. The transformation formula is included in the parameter file, for example. The scenario execution unit 101d executes the navigation simulator scenario including the sensor signal of a dimensionless quantity transformed by the multiplication (step S607). Thereafter, the scenario execution unit 101d outputs the navigation simulator scenario to the navigation simulator HW 4.

The emulation function unit 405b of the navigation simulator HW 4 generates an emulated sensor signal by performing emulation based on the virtual sensor signal or the simulator built-in sensor signal and outputs the emulated sensor signal to the test target 5 (step S608). The virtual sensor signal or the simulator built-in sensor signal is included in the navigation simulator scenario input from the PC 1. The emulated sensor signal is an electrical signal that is necessary for car navigation in the test target 5. After that, the scenario execution unit 101d of the PC 1 determines whether the execution of the navigation simulator scenario of the preset driving route has ended (step S609).

In the present embodiment, the navigation simulator HW 4 includes a register having a memory address same as a memory address of the car navigator built-in sensor 503 of the test target 5. The navigation simulator HW 4 may set, for the register, the same memory address as the car navigator built-in sensor 503 as follows. Specifically, for example, the parameter file includes register map information relative to the test target 5. At execution of simulation, the register map information is developed on a memory area of the navigation simulator HW 4, making it possible for the navigation simulator HW 4 to set the same memory address as that of the car navigator built-in sensor 503 in the register even when the test target 5 changes. With this configuration, in response to the request for the sensor signal from the test target 5, the emulation function unit 405b can read the emulated sensor signal corresponding to the requested sensor signal from the register and can output the emulated sensor signal to the test target 5. As a result, the test target 5 can acquire the emulated sensor signal at a higher speed as compared with the case where the test target 5 acquires the sensor signal from the PC 1. Therefore, the operation verification of the test target 5 can be executed in a state closer to real driving.

When the execution of the navigation simulator scenario is completed (step S609: Yes), the scenario execution unit 101d ends the execution of the navigation simulator scenario. In contrast, in a case where the execution of the navigation simulator scenario is not completed (step S609: No), the scenario execution unit 101d returns to step S605.

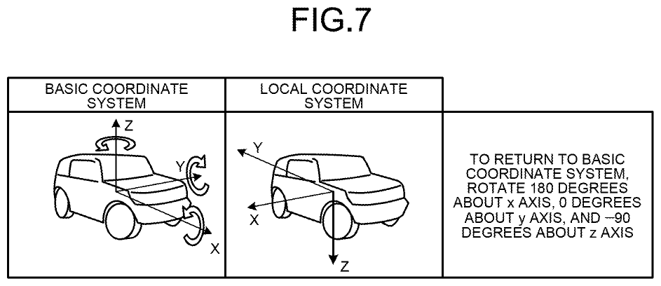

FIGS. 7 to 9 are diagrams each illustrating an example of an execution process of a navigation simulator scenario in the information processing system according to the present embodiment. Next, an example of the execution process of the navigation simulator scenario in the information processing system according to the present embodiment will be described with reference to FIGS. 7 to 9.

As illustrated in FIG. 7, assignment and attachment angles of x, y, and z axes might differ between the car navigator built-in sensor 503 and the simulator built-in sensor 404 in some cases. In the present embodiment, the PC 1 defines the coordinate system and the like of the simulator built-in sensor 404 as a basic coordinate system, and defines the coordinate system of the car navigator built-in sensor 503 as a local coordinate system. The PC 1 stores, in a storage unit such as the ROM, a parameter file including rotation angles of the local coordinate system based on the basic coordinate system for each type of the car navigator built-in sensor 503 (for example, 180 degrees about the x axis, 0 degrees about the y axis, and −90 degrees about the z axis: an example of attachment angles). In addition, the PC 1 stores, in the ROM or the like, a parameter file including a sensitivity coefficient for each type of the car navigator built-in sensor 503 based on the sensitivity coefficient of the simulator built-in sensor 404.

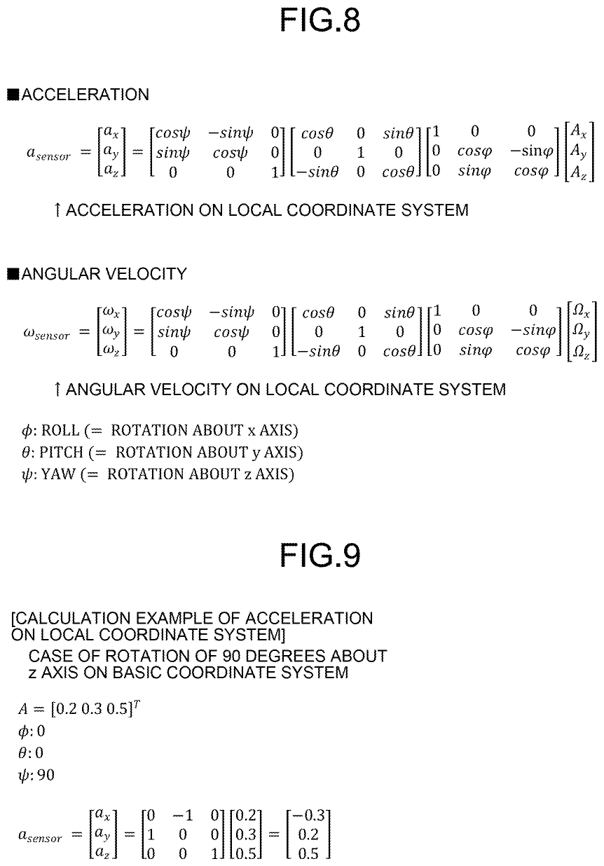

Subsequently, as illustrated in FIG. 8, the scenario execution unit 101d performs coordinate transformation on acceleration (Ax, Ay, Az) and angular velocity (Ωx, Ωy, Ωz) detected by the simulator built-in sensor 404 by using rotation matrix to obtain acceleration aₛₑₙₛₒᵣ and angular velocity ωₛₑₙₛₒᵣ in the local coordinate system of the car navigator built-in sensor 503. Both the acceleration and the angular velocity are each expressed by a matrix of three rows and one column. In one example, in a case where the local coordinate system of the simulator built-in sensor 404 is a coordinate system rotated by 90 degrees about the z axis of the basic coordinate system, the scenario execution unit 101d performs coordinate transformation on the acceleration A (0.2, 0.3, 0.5) detected by the simulator built-in sensor 404, by using the rotation matrix illustrated in FIG. 9. With this operation, the scenario execution unit 101d calculates the acceleration aₛₑₙₛₒᵣ (−0.3, 0.2, 0.5) in the local coordinate system, in which the values of the x axis and the y axis of the acceleration (0.2, 0.3, 0.5) detected by the simulator built-in sensor 404 have been exchanged. Similarly, the scenario execution unit 101d performs coordinate transformation on the angular velocity Ω to be transformed into the angular velocity ωₛₑₙₛₒᵣ on the local coordinate system.

In this manner, with the information processing system according to the present embodiment, the sensor signal necessary for the operation verification of the test target 5 can electrically be reproduced, making it possible to execute operation verifications on the test target 5 (for example, reproduction of a real driving log, pre-verification before real local driving, and driving route verification that is impossible in reality, such as wrong-way-driving). In addition, it is possible to verify the operation of the test target 5 without using large mechanical equipment such as a turntable.

Computer programs (for example, a program for implementing the scenario generation unit 101a, the log monitoring unit 101b, the scenario converter 101c, and the scenario execution unit 101d) executed by the PC 1 of the present embodiment are provided by being recorded in a computer-readable recording medium such as CD-ROM, a flexible disk (FD), a CD-R, and a digital versatile disk (DVD) as a file in an installable format or an executable format.

Moreover, the programs executed on the PC 1 in the present embodiment may be stored on a computer connected to a network such as the Internet and be provided by downloading via the network. Moreover, the programs executed on the PC 1 in the present embodiment may be provided or distributed via a network such as the Internet.

In addition, the programs executed by the PC 1 of the present embodiment may be provided by being incorporated beforehand in a medium such as ROM.

The program executed by the navigation simulator HW 4 of the present embodiment (for example, a program for implementing the data logging function unit 405a and the emulation function unit 405b) is provided by being incorporated beforehand in ROM or the like. The program executed by the navigation simulator HW 4 of the present embodiment may be provided by being recorded in a computer-readable recording medium such as CD-ROM, a flexible disk (FD), a CD-R, or a DVD as a file in an installable format or an executable format.

Moreover, the programs executed on the navigation simulator HW 4 of the present embodiment may be stored on a computer connected to a network such as the Internet and be provided by downloading via the network. Moreover, the programs executed on the navigation simulator HW 4 in the present embodiment may be provided or distributed via a network such as the Internet.

In addition, an information processing method executed by the PC 1 of the information processing system according to the present embodiment includes: a step of generating, by a generation unit, a virtual driving scenario including a virtual sensor signal representing motion information detected by a simulator built-in sensor installed in a navigation simulator when a vehicle virtually drives on a preset driving route; a step of acquiring, by an acquisition unit, a driving log file including a simulator built-in sensor signal representing motion information detected by the simulator built-in sensor when the vehicle drives on the driving route; a step of executing, by an execution unit, a test scenario including the virtual sensor signal included in the virtual driving scenario or the simulator built-in sensor signal included in the driving log file: and a step of outputting, by an output unit, the test scenario executed by the execution unit to the navigation simulator.

While certain embodiments have been described, these embodiments have been presented by way of example only, and are not intended to limit the scope of the inventions. Indeed, the novel methods and systems described herein may be embodied in a variety of other forms; moreover, various omissions, substitutions and changes in the form of the methods and systems described herein may be made without departing from the spirit of the inventions. The accompanying claims and their equivalents are intended to cover such forms or modifications as would fall within the scope and spirit of the inventions.

With the navigation simulator, the information processing device, and the recording medium according to the present disclosure, operation verification of a car navigation system can be executed by electrically reproducing a sensor signal necessary for operation verification of the car navigation system.

What is claimed is:

1. A navigation simulator comprising:
a memory in which a computer program is stored; and
a processor coupled to the memory and configured to perform processing by executing the computer program, the processing including:
acquiring, from an external device, a test scenario including a simulator built-in sensor signal, the simulator built-in sensor signal representing motion information detected by a simulator built-in sensor when a vehicle drives on a preset driving route, the simulator built-in sensor being installed in the navigation simulator;
generating an emulated sensor signal obtained by emulating a car navigator built-in sensor signal on the basis of the simulator built-in sensor signal included in the test scenario, the car navigator built-in sensor signal representing motion information detected by a car navigator built-in sensor installed in a car navigation system; and
outputting the generated emulated sensor signal to the car navigation system.

2. The navigation simulator according to claim 1, wherein
the processing further includes storing, in a storage medium, a driving log file including the simulator built-in sensor signal, and
the simulator built-in sensor signal represents, by a dimensionless quantity, the motion information detected by the simulator built-in sensor.

3. The navigation simulator according to claim 2, wherein the test scenario includes: the simulator built-in sensor signal included in the driving log file, or a virtual sensor signal output from the simulator built-in sensor when the vehicle virtually drives on the preset driving route.

4. The navigation simulator according to claim 3, wherein the emulated sensor signal is a signal obtained by converting the simulator built-in sensor signal or the virtual sensor signal into a signal with a format of a car navigator built-in sensor signal output by the car navigator built-in sensor.

5. The navigation simulator according to claim 2, wherein the processing includes acquiring the test scenario including the simulator built-in sensor signal representing, by a physical quantity, the simulator built-in sensor signal stored in the storage medium.

6. The navigation simulator according to claim 1, further comprising a register to which a same memory address as the car navigator built-in sensor is assigned, the register being configured to hold the emulated sensor signal, wherein
the processing further includes reading the emulated sensor signal corresponding to a sensor signal from the register in response to a request for the sensor signal from the car navigation system.

7. The navigation simulator according to claim 1, wherein the motion information includes information indicating angular velocity and acceleration of the vehicle.

8. An information processing device comprising:
a memory in which a computer program is stored; and
a processor coupled to the memory and configured to perform processing by executing the computer program, the processing including:
generating a virtual driving scenario including a virtual sensor signal, the virtual sensor signal representing motion information detected by a simulator built-in sensor when a vehicle virtually drives on a preset driving route, the simulator built-in sensor being installed in a navigation simulator;
acquiring a driving log file including a simulator built-in sensor signal, the simulator built-in sensor signal representing motion information detected by the simulator built-in sensor when the vehicle drives on the driving route;
executing a test scenario including the virtual sensor signal included in the virtual driving scenario or the simulator built-in sensor signal included in the driving log file; and
outputting the test scenario to the navigation simulator.

9. The information processing device according to claim 8, wherein the processing includes:
converting the simulator built-in sensor signal included in the driving log file into a sensor signal represented by a physical quantity;
generating the virtual driving scenario including the virtual sensor signal represented by a physical quantity;
multiplying, by a transformation rotation matrix, the virtual sensor signal included in the virtual driving scenario or the simulator built-in sensor signal included in the driving log file, the transformation rotation matrix corresponding to an attachment angle of a car navigator built-in sensor installed in a car navigation system;
multiplying, by a transformation formula, the simulator built-in sensor signal or the virtual sensor signal having been multiplied by the transformation rotation matrix, the transformation formula corresponding to a sensitivity coefficient of the car navigator built-in sensor; and
executing the test scenario including the simulator built-in sensor signal or the virtual sensor signal having been multiplied by the transformation formula.

10. The information processing device according to claim 8, wherein the processing includes:
generating a driving route on which the vehicle is caused to virtually drive by a dedicated map application; and
generating the virtual driving scenario on the basis of the generated driving route.

11. The information processing device according to claim 10, wherein the processing includes:
acquiring, by using the map application, latitude and longitude of a driving route on which operation verification of the car navigation system is to be performed;
generating the driving route by authoring on the basis of the latitude and longitude; and
generating, by physical computation, the virtual driving scenario including a sensor signal obtained in a case where the vehicle model is caused to drive on the generated driving route.

12. The information processing device according to claim 8, wherein the motion information includes angular velocity and acceleration of the vehicle.

13. A non-transitory computer-readable recording medium on which programmed instructions are recorded, the instructions causing a computer to execute processing, the processing comprising:
acquiring, from an external device, a test scenario including a simulator built-in sensor signal, the simulator built-in sensor signal representing motion information detected by a simulator built-in sensor when a vehicle drives on a preset driving route, the simulator built-in sensor being installed in the navigation simulator;
generating an emulated sensor signal obtained by emulating a car navigator built-in sensor signal on the basis of the simulator built-in sensor signal included in the test scenario, the car navigator built-in sensor signal representing motion information detected by a car navigator built-in sensor installed in a car navigation system; and
outputting the generated emulated sensor signal to the car navigation system.
